(19) United States
(12) Patent Application Publication
(10) Pub. No.: US 2026/0190948 A1
(43) Pub. Date: Jul. 2, 2026

(54) MULTI-AXIS STAGE APPARATUS, WAFER BONDING METHOD, AND WAFER BONDING APPARATUS USING THE SAME

(71) Applicant: SEMES CO., LTD., Chungcheongnam-do (KR)

(72) Inventors: Dongwook LIM, Chungcheongnam-do (KR); Kyoungho EO, Chungcheongnam-do (KR)

(21) Appl. No.: 19/372,397

(22) Filed: Oct. 29, 2025

(30) Foreign Application Priority Data
Dec. 31, 2024 (KR) 10-2024-0203018
Feb. 11, 2025 (KR) 10-2025-0017562

(51) Int. Cl. H01L 21/687; H01L 21/18; H01L 21/67; H01L 21/68

(52) U.S. Cl. CPC H10P 72/7618; H10P 10/12; H10P 72/0428; H10P 72/53; H10P 72/7624

(57) ABSTRACT

The present invention relates to a multi-axis stage apparatus capable of significantly improving the precision of wafer bonding, a wafer bonding method using the apparatus, and a wafer bonding apparatus. The apparatus includes a base, an alignment stage configured to align a first wafer held by a first wafer chuck, a first driving device positioned between the base and the alignment stage and configured to vertically move the alignment stage with low precision, and a second driving device also positioned between the base and the alignment stage and configured to vertically move the alignment stage with high precision. The second driving device may include a flexure hinge, at least a portion of which is configured to distribute load. By combining coarse and fine vertical movement control and supporting structures based on flexure mechanics, the apparatus enables precise multi-axis alignment and bonding of wafers.

### CROSS-REFERENCE TO RELATED PATENT APPLICATION

This application claims the benefit under 35 U.S.C. § 119 of Korean Patent Application No. 10-2024-0203018, filed on Dec. 31, 2024, and Korean Patent Application No. 10-2025-0017562, filed on Feb. 11, 2025, the disclosures of which are hereby incorporated by reference in their entirety.

### BACKGROUND

### 1. Field of the Disclosure

The present disclosure relates to a multi-axis stage apparatus, a wafer bonding method using the same, and a wafer bonding apparatus. More particularly, it relates to a multi-axis stage apparatus that can significantly improve the precision of wafer bonding, and a wafer bonding method and apparatus using the same.

### 2. Description of the Related Art

A semiconductor manufacturing process is a process for forming semiconductor devices on a substrate (e.g., a wafer), and may include, for example, exposure, deposition, etching, ion implantation, and cleaning.

To perform each of the manufacturing processes, semiconductor manufacturing equipment for each process is provided in a cleanroom of a semiconductor fabrication plant, and process treatment is performed on substrates introduced into the manufacturing equipment.

Meanwhile, in order to produce semiconductor products in which multiple substrates are stacked, such as High Bandwidth Memory (HBM), wafer-to-wafer (W2W) bonding processes for bonding wafers to each other have been developed. Such conventional wafer bonding processes broadly include a step of aligning wafers with each other and a step of bringing the wafers into close contact.

However, in conventional wafer bonding apparatuses, to secure a sufficient stroke, a single driving device with micrometer- or millimeter-level precision is used to move wafers in the Z-axis direction. Therefore, achieving nanometer-level high precision has been mechanically very difficult, and even if the precision of the single driving device is improved, the vertical movement speed becomes very slow, resulting in many problems.

In addition, conventional wafer bonding apparatuses are configured such that during multi-axis movement and rotation of the wafer chuck in the X-axis, Y-axis, Z-axis, first rotational axis, second rotational axis, and theta axis (third rotational axis), ball joints or the like are used. As a result, mechanical errors or component damage may easily occur, and mechanical deformation or thermal deformation due to loads is also prone to occur.

### SUMMARY OF THE DISCLOSURE

The present disclosure has been devised to solve the aforementioned and other problems, and it is an object of the present disclosure to provide a multi-axis stage apparatus, a wafer bonding method using the same, and a wafer bonding apparatus, which can significantly improve the precision of wafer bonding by using two driving devices with different levels of precision for vertical movement along the Z-axis. However, such problems are illustrative only and do not limit the scope of the disclosure.

According to the inventive concept of the present disclosure devised to solve the aforementioned problem, a multi-axis stage apparatus includes a base, an alignment stage that aligns a first wafer chuck on which a first wafer is held; a first driving device formed between the base and the alignment stage and configured to move the alignment stage vertically with low precision, and a second driving device formed between the base and the alignment stage and configured to move the alignment stage vertically with high precision. The second driving device may include a flexure hinge having at least a portion configured to distribute load.

Meanwhile, a wafer bonding method using the multi-axis stage apparatus according to the inventive concept of the present disclosure for solving the above problem may include (a) a step of transferring a second wafer below a second wafer chuck by a second wafer transfer arm, wherein a picker of the second wafer chuck picks up the second wafer and brings it into close contact with the second wafer chuck, and the second wafer chuck holds the second wafer in the close-contacted state, (b) a step of identifying the position of the second wafer using a first camera formed on the first wafer chuck or on the alignment stage, (c) a step of loading the first wafer onto lift pins of the first wafer chuck by a first wafer transfer arm, while coarsely moving the first wafer chuck vertically with low precision by the first driving device, (d) a step of precisely aligning the first wafer in a first axial direction, a second axial direction, and a theta-axis direction with reference to the position-confirmed second wafer by a second camera formed on the second wafer chuck and the alignment stage, and (e) a step of bonding the aligned first wafer and the second wafer while precisely moving the first wafer chuck vertically with high precision by the second driving device having a flexure hinge.

According to the inventive concept of the present disclosure devised to solve the aforementioned problem, a wafer bonding apparatus includes a base, an alignment stage that aligns a first wafer chuck holding a first wafer, a first driving device formed between the base and the alignment stage and configured to move the alignment stage vertically with low precision; and a second driving device formed between the base and the alignment stage and configured to move the alignment stage vertically with high precision.

The second driving device includes a flexure hinge having a portion configured to distribute load. The second driving device may include a plurality of first voice coil motors (VCMs) isometrically arranged around a central axis for vertical movement, a movable stage having the flexure hinge, a portion of which is fixed and another portion of which is configured to move vertically with high precision by the first voice coil motors, and a flexure joint formed on the movable stage and providing multiple degrees of freedom.

The movable stage may include an inner pillar portion that is vertically formed and configured to distribute load along a first path, an outer pillar portion that is vertically formed outside the inner pillar portion and configured to distribute load along a second path, a precision elevation portion formed between the inner and outer pillar portions and configured to move vertically with high precision by the first voice coil motors to distribute load along a third path, and flexure hinges formed between the inner pillar portion and the precision elevation portion and between the outer pillar portion and the precision elevation portion, configured to elastically support the precision elevation portion.

The first driving device may move at least a portion of the alignment stage in a third axial direction by a first distance with respect to the base. The second driving device may move at least a portion of the alignment stage in the third axial direction by a second distance with respect to the first driving device. The alignment stage is connected to the second driving device such that the first wafer can be moved in the third axial direction by a distance equal to the sum of the first distance and the second distance.

The first driving device is configured to move the first wafer vertically with low precision by the first distance, which is relatively longer than the second distance. The second driving device is configured to move the first wafer vertically with high precision by the second distance, which is relatively shorter than the first distance.

The alignment stage may align the first wafer in a first axial direction, a second axial direction, and a theta-axis direction using a second voice coil motor or a piezoelectric element. The alignment stage may include a stage jig, a flexure frame including a portion fixed to the stage jig and another portion that is elastically deformable with respect to the stage jig, and at least one second voice coil motor formed on the stage jig and configured to elastically deform the another portion of the flexure frame.

According to various embodiments of the present disclosure configured as described above, for vertical movement along the Z-axis, both a first driving device with a relatively long stroke and low precision and a second driving device with a relatively short stroke and high precision may be utilized together, thereby significantly improving the bonding precision and process speed of the wafer bonding operation. In addition, by employing voice coil motors and flexure joints, mechanical errors and component damage during multi-axis driving can be effectively prevented. Furthermore, by distributing loads along multiple paths, mechanical deformation and thermal distortion of components due to loads can be minimized, thereby greatly enhancing the productivity, durability, and reliability of the resulting product. It should be understood, however, that the scope of the present invention is not limited to the effects described above.

### BRIEF DESCRIPTION OF THE DRAWINGS

The above and other features and advantages of the present disclosure will become more apparent by describing in detail embodiments thereof with reference to the attached drawings in which:

FIG. 1 is a side sectional view conceptually showing a multi-axis stage apparatus according to some embodiments of the present disclosure.

FIG. 2 is an exploded perspective view showing the multi-axis stage apparatus of FIG. 1.

FIG. 3 is a perspective view showing the alignment stage of the multi-axis stage apparatus of FIG. 2.

FIG. 4 is a plan view showing the alignment stage of the multi-axis stage apparatus of FIG. 3.

FIG. 5 is a perspective view showing the second driving device of the multi-axis stage apparatus of FIG. 2.

FIG. 6 is a perspective view showing the movable stage of the second driving device of FIG. 5.

FIG. 7 is a perspective view showing the flexure joint of the second driving device of FIG. 5.

FIG. 8 is a perspective view showing the first driving device of the multi-axis stage apparatus of FIG. 2.

FIGS. 9 through 20 are cross-sectional views sequentially illustrating the wafer bonding process using the multi-axis stage apparatus of FIG. 1.

FIG. 21 is a flowchart illustrating a wafer bonding method using a multi-axis stage apparatus according to some embodiments of the present disclosure.

### DETAILED DESCRIPTION OF THE DISCLOSURE

Hereinafter, preferred embodiments of the present disclosure will be described in detail with reference to the accompanying drawings.

The embodiments of the present disclosure are provided to more fully explain the disclosure to those skilled in the art. Various modifications may be made to the following embodiments, and the scope of the present disclosure is not limited thereto. Rather, these embodiments are provided to fully convey the spirit of the disclosure and to enable those skilled in the art to understand the disclosure in its entirety. In addition, the thickness and size of each layer shown in the drawings are exaggerated for ease of explanation and clarity.

The terminology used herein is for the purpose of describing particular embodiments only and is not intended to be limiting of the present disclosure. As used herein, the singular forms “a,” “an,” and “the” are intended to include the plural forms as well, unless the context clearly indicates otherwise.

Furthermore, the terms “comprise” and/or “comprising,” as used herein, specify the presence of stated features, numbers, steps, operations, members, elements, and/or groups thereof, but do not preclude the presence or addition of one or more other features, numbers, steps, operations, members. elements, components, and/or groups thereof.

Hereinafter, embodiments of the present disclosure will be described with reference to the accompanying drawings, which illustrate exemplary embodiments of the present disclosure. It should be understood that variations in the illustrated configurations may occur due to, for example, manufacturing techniques and/or tolerances. Accordingly, embodiments of the inventive concept should not be construed as being limited to the specific shapes or regions illustrated in the present specification, but should be understood to include variations in shape resulting from, for example, manufacturing processes.

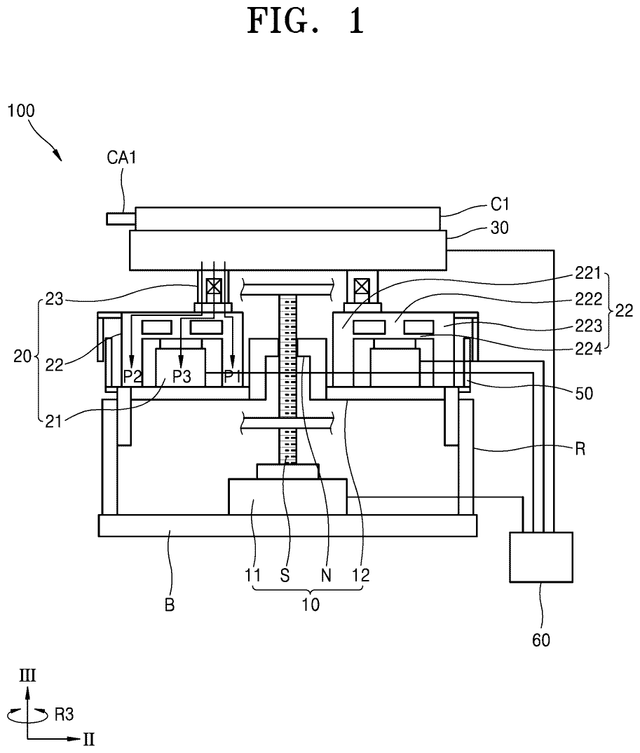

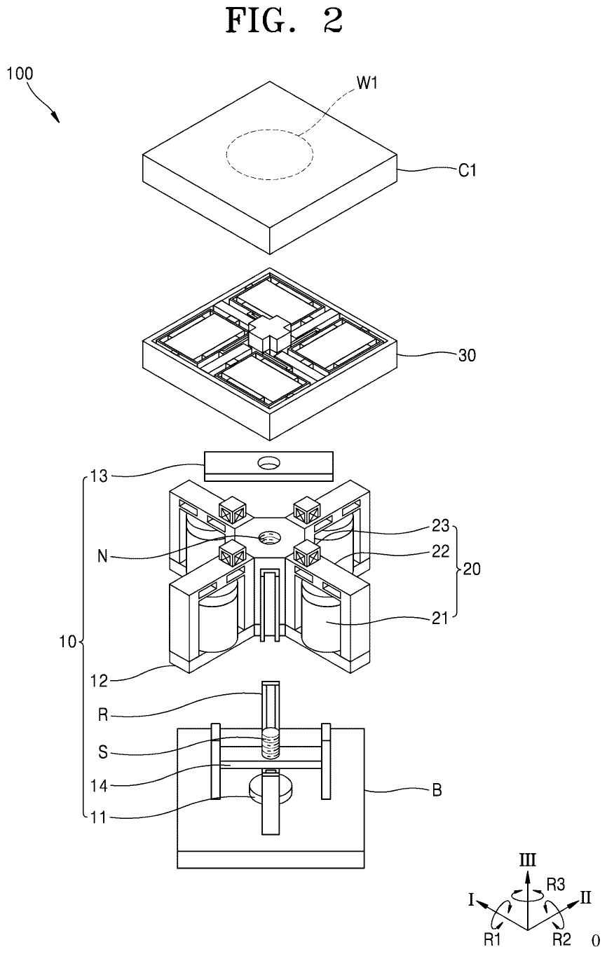

FIG. 1 is a side cross-sectional view illustrating a multi-axis stage apparatus 100 according to some embodiments of the present disclosure, and FIG. 2 is an exploded perspective view of the multi-axis stage apparatus 100 shown in FIG. 1.

Referring first to FIGS. 1 and 2, the multi-axis stage apparatus 100 according to some embodiments of the present disclosure may generally include a base B, a first driving device 10, a second driving device 20, and an alignment stage 30.

The base B may serve as a support structure having sufficient strength and durability to support the first driving device 10, the second driving device 20, and the alignment stage 30, and to withstand the pressure applied during wafer bonding. The base B is not necessarily limited to the illustrated drawings and may include various types and shapes of three-dimensional structures.

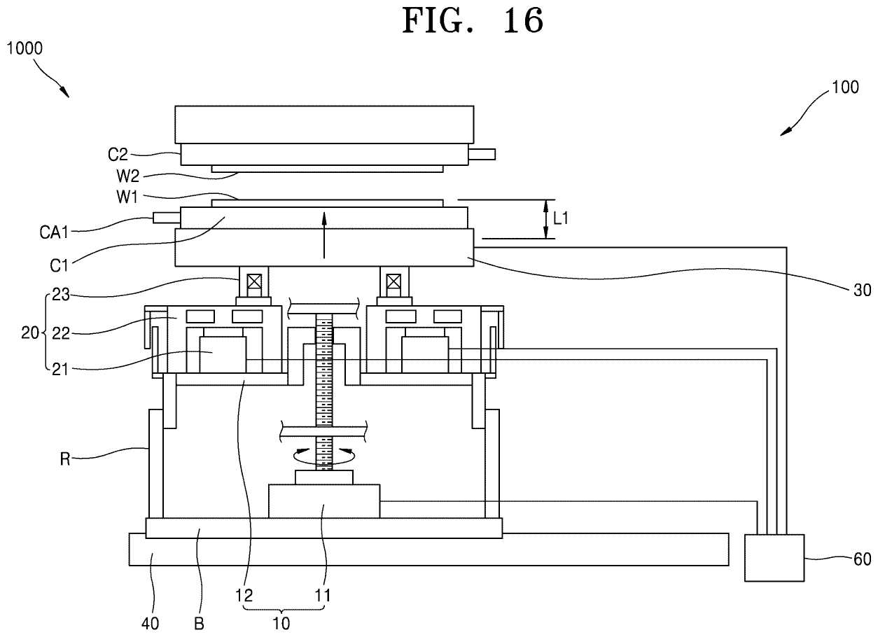

The first driving device 10 may be, for example, a type of primary vertical driving device that is formed on the base B or between the base B and the alignment stage 30, and is configured to move at least a portion of the alignment stage vertically in a third axial direction III by a first distance L1 (see FIG. 16) relative to the base B with relatively low precision in a coarse manner.

Here, the third axial direction III refers to a vertical direction perpendicular to a plane (horizontal plane) defined by a first axial direction I and a second axial direction II. For example, the third axial direction III may be the Z-axis direction along which the first wafer W1 is moved up and down. The second axial direction II may correspond to the Y-axis direction, which is the main direction in which the first wafer W1 is loaded and unloaded, and the first axial direction I may correspond to the X-axis direction, which is perpendicular to the second axial direction II. However, the first, second, and third axial directions I, II, and III are not necessarily limited to those illustrated in the drawings, and any mutually orthogonal directions may be applied.

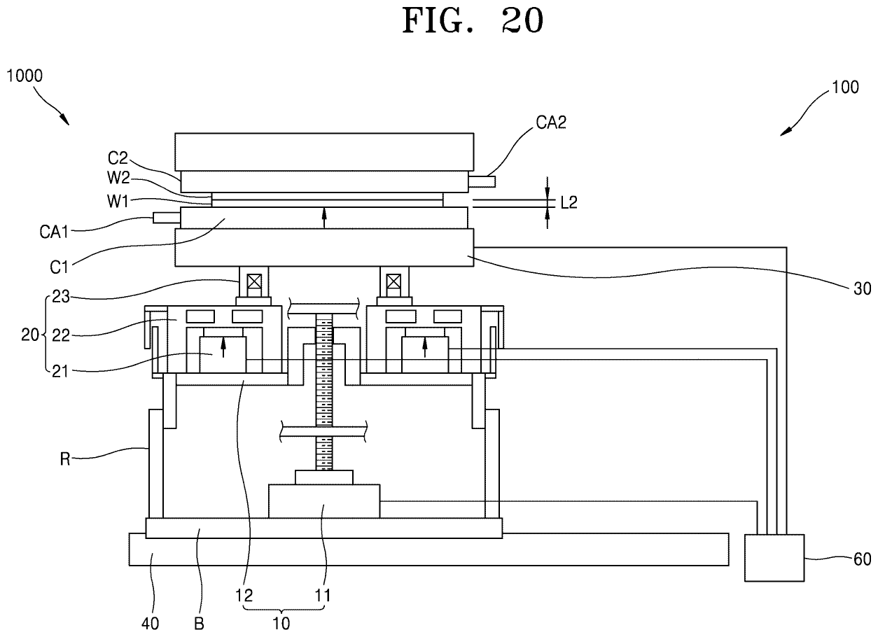

The second driving device 20 may be, for example, a type of secondary vertical driving device that is formed on the first driving device 10 or between the base B and the alignment stage 30, and is configured to move at least a portion of the alignment stage 30 vertically in the third axial direction III by a second distance L2 (see FIG. 20) relative to the first driving device 10 with relatively high precision.

The first driving device 10 may be configured to move the first wafer W1 vertically by the first distance L1, which is relatively longer than the second distance L2, in a coarse manner. For example, the first driving device 10 may be a relatively low-precision vertical drive system that is capable of moving the first wafer W1 up and down with low precision on the order of micrometers, millimeters, or greater by using a ball screw or a lead screw. In addition, the second driving device 20 may be configured to move the first wafer W1 vertically by a second distance L2, which is relatively shorter than the first distance L1, with high precision. For example, the second driving device 20 may be a relatively high-precision vertical drive system that uses a first voice coil motor (VCM; Voice Coil Motor) or a piezoelectric element to move the first wafer W1 with high precision on the order of nanometers or less.

The second driving device 20 may include a flexure hinge 224 having at least a portion configured to distribute load.

For the purpose of mechanical illustration, the drawings depict an example in which the second driving device 20 is formed on top of the first driving device 10. However, it is also possible to form the first driving device 10 on top of the second driving device 20.

The alignment stage 30 may be connected to the second driving device 20 so that the first wafer W1 can be moved vertically in the third axial direction III by a distance corresponding to the sum of the first distance L1 and the second distance L2. The alignment stage 30 may be a type of alignment mechanism that aligns a first wafer chuck C1 holding the first wafer W1. The first wafer chuck C1 may be, for example, a vacuum chuck or an electrostatic chuck.

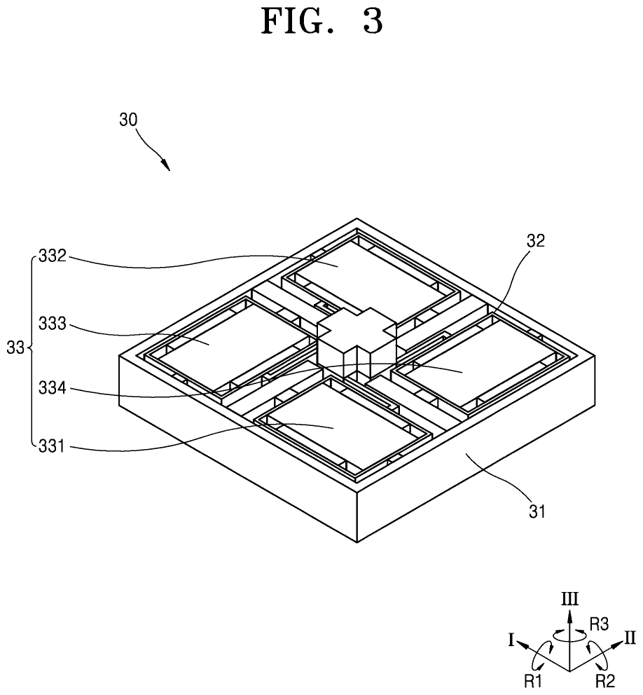

The alignment stage 30 may align the first wafer W1 in the first axial direction I, the second axial direction II, and a theta-axis direction R3 using, for example, a second voice coil motor 33 (see FIG. 3) or a piezoelectric element.

Here, the theta-axis direction R3 may be a rotational direction about the third axial direction III as a rotational axis within a plane defined by the first axial direction I and the second axial direction II. However, the rotational direction is not necessarily limited to that illustrated in the drawings, and various rotational directions may be applied.

More specifically, as illustrated in FIGS. 1 and 2, the first driving device 10 may include a drive motor 11 that is formed on the base B and a movable frame 12. The movable frame 12 may be guided along a vertical movement path by a rail member R formed on the base B, and may include a nut member N configured to move vertically by the rotation of a screw shaft S.

As illustrated in FIGS. 1 and 2, the second driving device 20 may include a plurality of first voice coil motors (VCMs) 21 (four in the illustrated embodiment) which are isometrically arranged around the nut member N of the screw shaft on a central axis for vertical movement or on the movable frame 12, a movable stage 22 having a flexure hinge 224, wherein a portion of the movable stage is relatively fixed and another portion is configured to move vertically with high precision by the first voice coil motors 21, and a flexure joint 23 formed on the movable stage 22 and providing multiple degrees of freedom.

Here, the first voice coil motors 21 may be isometrically arranged in a quadrangular configuration around the nut member N on the movable frame 12, so as to reduce installation cost by decreasing the volume of each unit and to increase the number of installed units, thereby distributing load and enabling the first wafer W1 to rotate about a first rotational axis R1 or a second rotational axis R2. However, the arrangement of the first voice coil motors 21 is not necessarily limited to a quadrangular layout. For example, the motors may be arranged in a triangular, pentagonal, hexagonal, or other isometric configuration around the nut member N on the movable frame 12.

Here, the first rotational axis R1 may be a rotational direction about the first axial direction I within a plane defined by the second axial direction II and the third axial direction III, and the second rotational axis R2 may be a rotational direction about the second axial direction II within a plane defined by the first axial direction I and the third axial direction III. However, the first and second rotational axes R1 and R2 are not necessarily limited to those illustrated in the drawings, and various other rotational directions may be applied.

The voice coil motor (VCM; Voice Coil Motor) may be a type of linear motor that operates based on the principle of a speaker and is capable of inducing a highly precise linear motion in proportion to the current flowing through a coil placed within a magnetic field generated by a permanent magnet.

However, in the second driving device 20 of the present disclosure, various types of precision motors, such as a piezo motor using a piezoelectric element, may be applied in place of the first voice coil motors 21.

In addition, the flexure joint 23, unlike a ball joint, may be a joint that uses a leaf spring, a coil spring, or another complex three-dimensional spring hinge, and can sufficiently absorb elastic deformation, thereby preventing mechanical errors or component damage.

Accordingly, when a plurality of first voice coil motors 21 are used, for example, if all of the first voice coil motors 21 are extended or contracted equally, the alignment stage 30 can be moved vertically in the third axial direction III with high precision. If at least one or more of the first voice coil motors 21 are extended or contracted differently, the alignment stage 30 can be tilted and rotated about the first rotational axis R1 or the second rotational axis R2.

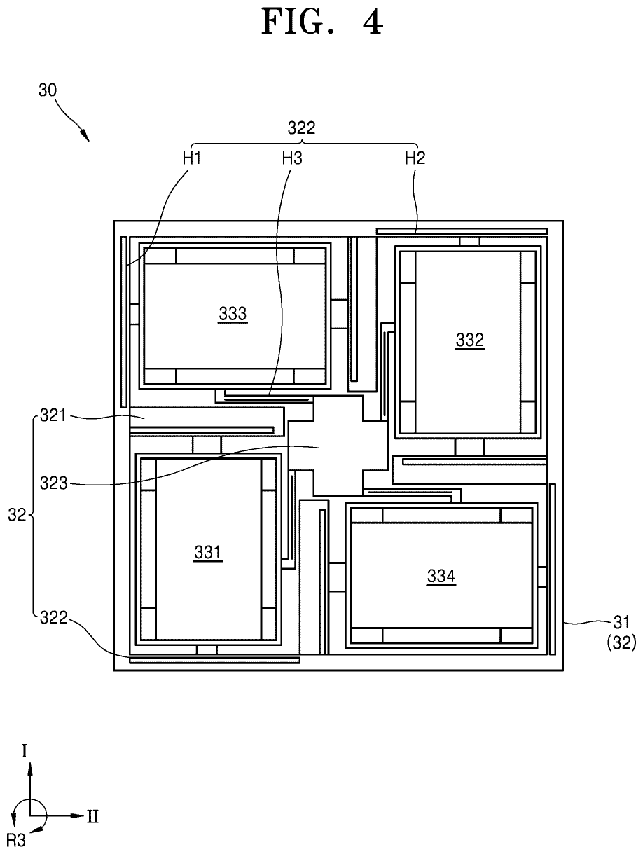

FIG. 3 is a perspective view illustrating the alignment stage 30 of the multi-axis stage apparatus 100 shown in FIG. 2, and FIG. 4 is a plan view illustrating the alignment stage of the multi-axis stage apparatus shown in FIG. 3.

As illustrated in FIGS. 1 to 4, the alignment stage 30 of the multi-axis stage apparatus 100 according to some embodiments of the present invention may be installed, for example, on the above-described base B, on the first driving device 10, between the second driving devices 20, or on the second driving device 20. The alignment stage 30 may include a stage jig 31, a flexure frame 32 having one portion fixed to the stage jig 31 and another portion that is elastically deformable relative to the stage jig 31, and at least one second voice coil motor 33 formed on the stage jig 31 and configured to elastically deform the other portion of the flexure frame 32.

More specifically, the flexure frame 32 may include a fixed portion 321 fixed to the stage jig 31, a flexure hinge 322 formed on the fixed portion 321 and made of an elastic material, and a movable portion 323 that supports the first wafer chuck C1 and is elastically and precisely displaceable by means of the flexure hinge 322.

For example, as illustrated in FIG. 4, the flexure hinge 322 may include at least one first hinge H1 that is elongated in the first axial direction I and elastically deformable in the second axial direction II, at least one second hinge H2 that is elongated in the second axial direction II and elastically deformable in the first axial direction, and at least one rotational hinge H3 formed on the movable portion 323 to enable rotation of the movable portion 323 in the theta-axis direction R3.

Accordingly, by using the first hinge H1, the second hinge H2, and the rotational hinge H3 of the flexure hinge 322, the movement of the movable portion 323 in the first axial direction I, the second axial direction II, and the theta-axis direction R3 can be precisely and elastically guided according to the amount of power applied to each of the second voice coil motors 33.

For example, the second voice coil motors 33 may include a total of four voice coil motors, comprising a first-axis forward voice coil motor 331 formed on one side of the movable portion 323 and arranged in the forward direction along the first axial direction I, a first-axis reverse voice coil motor 332 formed on the opposite side of the movable portion 323 and arranged in the reverse direction along the first axial direction I so that the movable portion 323 can be precisely translated in the first axial direction I or precisely rotated in the theta-axis direction R3, a second-axis forward voice coil motor 333 formed on another side of the movable portion 323 and arranged in the forward direction along the second axial direction II, and a second-axis reverse voice coil motor 334 formed on yet another side of the movable portion 323 and arranged in the reverse direction along the second axial direction II so that the movable portion 323 can be precisely translated in the second axial direction II or precisely rotated in the theta-axis direction R3.

Accordingly, for example, among the four second voice coil motors 33 installed on the stage jig 31, if the first-axis forward voice coil motor 331 is extended while the first-axis reverse voice coil motor 332 is contracted, the movable portion 323 can be precisely translated in the first axial direction I. If both the first-axis forward voice coil motor 331 and the first-axis reverse voice coil motor 332 are extended simultaneously, the movable portion 323 can be precisely rotated in the theta-axis direction R3. Based on the same principle, by using the second-axis forward voice coil motor 333 and the second-axis reverse voice coil motor 334, the movable portion 323 can be precisely translated in the second axial direction II or precisely rotated in the theta-axis direction R3.

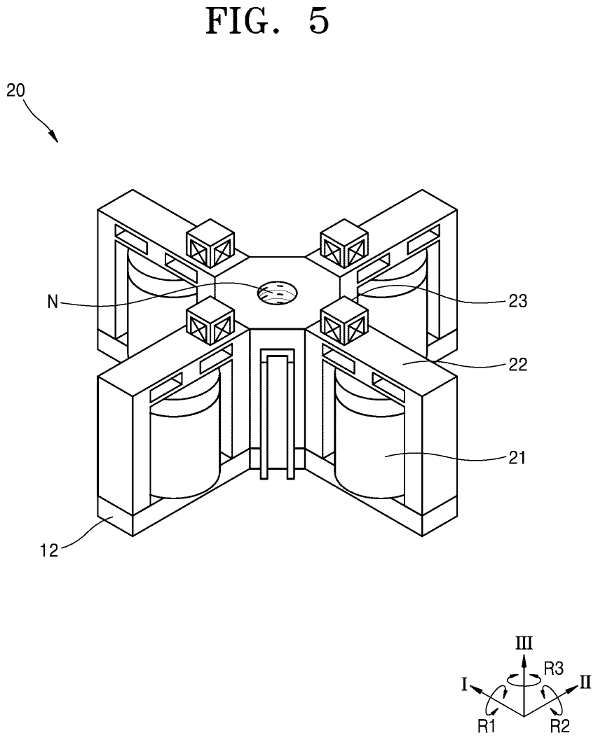

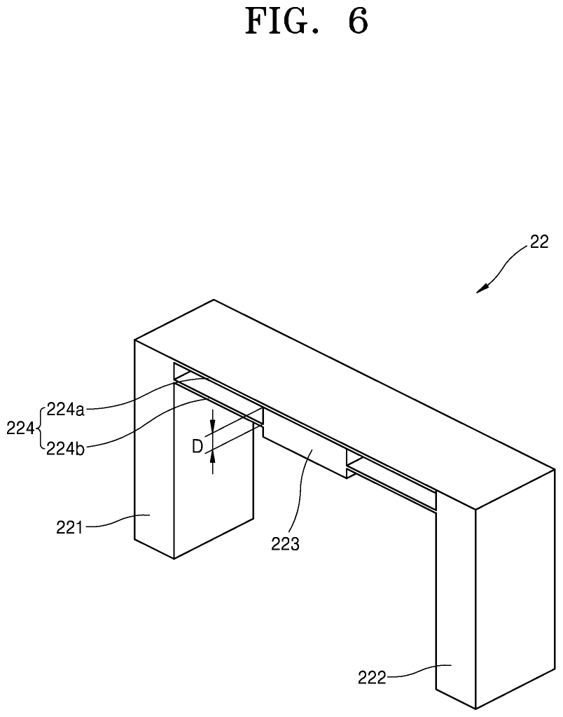

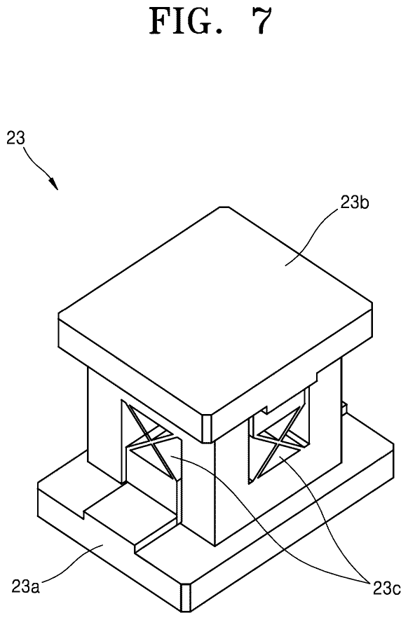

FIG. 5 is a perspective view illustrating the second driving device 20 of the multi-axis stage apparatus 100 shown in FIG. 2, FIG. 6 is a perspective view illustrating the movable stage 22 of the second driving device 20 shown in FIG. 5, and FIG. 7 is a perspective view illustrating the flexure joint 23 of the second driving device 20 shown in FIG. 5.

As illustrated in FIGS. 5 to 7, the second driving device 20 of the multi-axis stage apparatus 100 according to some embodiments of the present invention may include, for example, four first voice coil motors 21 isometrically arranged around the nut member N on the movable frame 12, a movable stage 22 having a flexure hinge 224, with one portion relatively fixed and another portion vertically movable with high precision by the first voice coil motors 21, and a flexure joint 23 formed on the movable stage 22 and providing multiple degrees of freedom.

As illustrated in FIG. 6, the movable stage 22 may include an inner pillar portion 221 vertically formed to distribute load along a first path P1 (see FIG. 1), an outer pillar portion 222 vertically formed outside the inner pillar portion 221 to distribute load along a second path P2, a precision elevation portion 223 formed between the inner pillar portion 221 and the outer pillar portion 222 to distribute load along a third path P3, and vertically moved with high precision by the first voice coil motors 21, and flexure hinges 224 formed respectively between the inner pillar portion 221 and the precision elevation portion 223, and between the outer pillar portion 222 and the precision elevation portion 223, the flexure hinges being configured to elastically support the precision elevation portion 223.

Here, for example, the inner pillar portion 221 and the outer pillar portion 222 may be relatively fixed with respect to the above-described movable frame 12 (see FIG. 1), and the precision elevation portion 223 may be elastically and highly precisely moved in the vertical direction by the first voice coil motors 21.

More specifically, the flexure hinge 224 may be a type of dual-hinge structure configured to elastically support the precision elevation portion 223 such that it can be vertically moved with high precision. The flexure hinge 224 may include an upper bridge portion 224a formed above the precision elevation portion 223, and a lower bridge portion 224b formed at a middle or lower portion of the precision elevation portion 223, spaced apart from the upper bridge portion 224a by a distance (or a gap) D and formed in parallel with the upper bridge portion 224a, so that the precision elevation portion 223 can move in the vertical direction as a whole.

Accordingly, by utilizing the flexure hinge 224 having the above-described dual-hinge structure, the precision elevation portion 223 can be moved vertically with high precision, and as illustrated in FIG. 1, loads such as the weight of upper components or pressing pressure can be distributed along multiple paths, including the first path P1, the second path P2, and the third path P3. This improves the durability of components subjected to external forces, prevents component damage caused by impact, and significantly reduces the portion of the load transmitted to the first voice coil motors 21, thereby minimizing heat generation due to load in the first voice coil motors 21.

As illustrated in FIG. 7, the flexure joint 23 may include a joint fixing portion 23a fixed to the movable stage 22, a joint movable portion 23b that is elastically movable with respect to the joint fixing portion 23a, and a joint flexure hinge 23c formed between them.

Here, the joint fixing portion 23a, the joint movable portion 23b, and the joint flexure hinge 23c are not limited to the illustrated forms and may adopt a variety of three-dimensional structures.

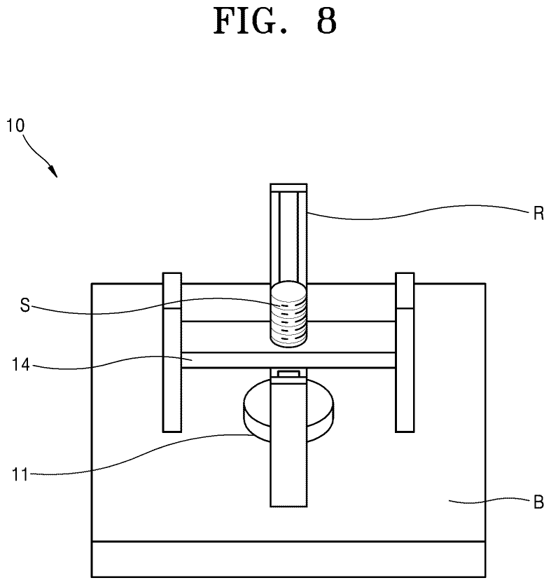

FIG. 8 is a perspective view illustrating the first driving device 10 of the multi-axis stage apparatus 100 shown in FIG. 2.

As illustrated in FIGS. 1 and 8, the first driving device 10 may include a drive motor 11 formed on the base B and configured to rotate a screw shaft S, and a movable frame 12 guided along a vertical movement path by a rail member R formed on the base B. The movable frame 12 may include a nut member N threadably engaged with the screw shaft S at a central portion thereof, such that when the screw shaft S rotates, the nut member N moves vertically along the shaft.

The drive motor 11 may be, for example, a direct drive (DD) motor configured to directly drive the screw shaft S without a separate power transmission mechanism or actuator to enhance precision. Alternatively, various types of motors such as a servo motor may also be used.

In addition, the movable frame 12 may be implemented as a disk- or polygonal-shaped plate in which the nut member N coupled with the screw shaft S is formed at a central position to uniformly apply the center of gravity.

The screw shaft S may be rotatably supported by supports 13 and 14 formed on the base B, and these supports may be assembled to the base B in a detachable manner using screws or bolts to facilitate component assembly.

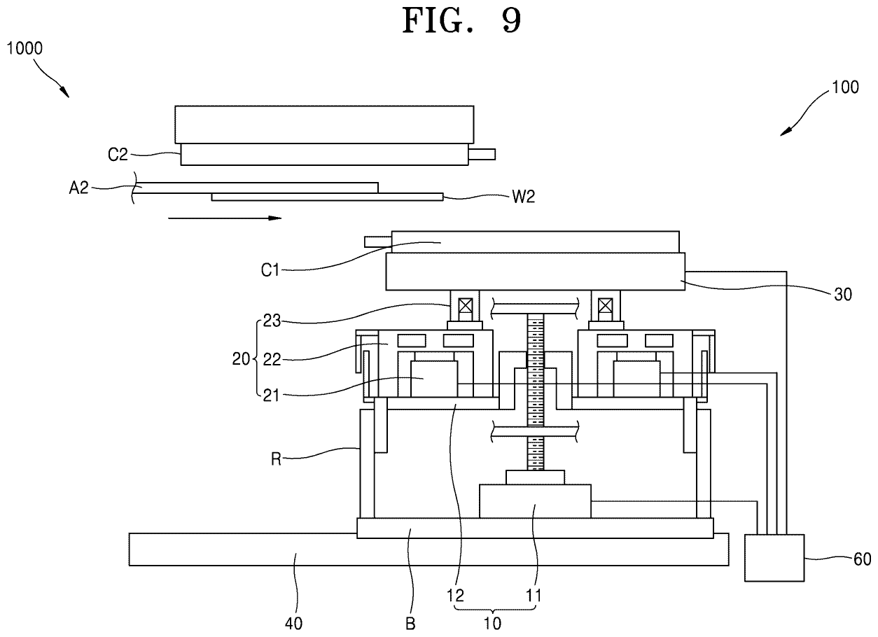

Accordingly, in the first driving device 10, when the drive motor 11 rotates the screw shaft S clockwise or counterclockwise, the nut member N threadably engaged with the screw shaft S moves vertically, thereby raising or lowering the movable frame 12. If necessary, the vertical movement path of the movable frame 12 may be guided by a rail member R such as a linear motion guide (LMG) formed on the base B. FIGS. 9 to 20 are sectional views sequentially illustrating a wafer bonding process using the multi-axis stage apparatus 100 shown in FIG. 1.

As illustrated in FIGS. 1 and 9, the multi-axis stage apparatus 100 according to some embodiments of the present invention may further include a transfer device 40 configured to move the base B back and forth to a position corresponding to a second wafer chuck C2 on which a second wafer W2 is held, so that the second wafer W2 can be bonded to a first wafer W1.

The multi-axis stage apparatus 100 may also include a first camera CA1 formed on the first wafer chuck C1 or the alignment stage 30, and configured to capture a second identifier M2 of the second wafer W2, a measurement device 50 such as an encoder, configured to measure a vertical displacement of the first wafer W1 or the first wafer chuck C1, and a controller 60 that receives an image signal from the first camera CA1 or a measurement signal from the measurement device 50, and applies control signals to at least one of the first driving device 10, the second driving device 20, the alignment stage 30, and the transfer device 40, or any combination thereof.

The measurement device 50 may employ various types of encoders or sensors that convert a position or distance of an object into electrical signals, and may include, for example, a linear encoder capable of detecting an angular range of 0.5 degrees.

The controller 60 may be implemented with various types of control systems including microprocessors, central processing units (CPUs), arithmetic processors, I/O interfaces, memory storing control programs, personal computers, server computers, networks, smartphones, tablet devices, smart devices, control boards, control chips, control components, and electronic components. In a first wafer loading mode in which the first wafer W1 is loaded onto the first wafer chuck C1 and held thereby, the controller 60 may apply a first-stage vertical control signal to the first driving device 10. In an alignment mode in which the first wafer W1 is precisely aligned with reference to the position-confirmed second wafer W2 in the first axial direction I, the second axial direction II, and the theta-axis direction R3, the controller may apply an alignment control signal to the alignment stage 30. In a bonding mode in which the aligned first wafer W1 and second wafer W2 are bonded together, the controller may apply a second-stage vertical control signal to the second driving device 20.

As shown in FIG. 9, a wafer bonding apparatus 1000 including the multi-axis stage apparatus 100 according to some embodiments of the present invention may include a second wafer chuck C2, which is fixed in an upper position and holds the second wafer W2, a first wafer chuck C1 disposed in a lower position such that its position is variably adjustable and configured to hold the first wafer W1, and the above-described multi-axis stage apparatus 100 that supports and aligns the first wafer W1 to a target position to allow bonding with the second wafer W2.

Here, the second wafer chuck C2 may be implemented as either a vacuum chuck or an electrostatic chuck.

It should be understood that the multi-axis stage apparatus 100 is structurally and functionally identical to the one described in FIGS. 1 to 9, and therefore, a redundant description thereof will be omitted.

Accordingly, as illustrated in FIGS. 9 to 20, the operation process of the wafer bonding apparatus 100 according to some embodiments of the present invention will now be described step-by-step. First, as shown in FIG. 9, a second wafer transfer arm A2 may transfer the second wafer W2 to a position below the second wafer chuck C2. In this case, the second wafer transfer arm A2 may load the second wafer W2 either by vacuum-adsorbing a portion of the back surface of the inverted second wafer W2 or by clamping the side of the second wafer W2.

At this time, in order to secure sufficient loading space for the second wafer W2, the first driving device 10 may descend with a relatively long stroke and remain in a standby position.

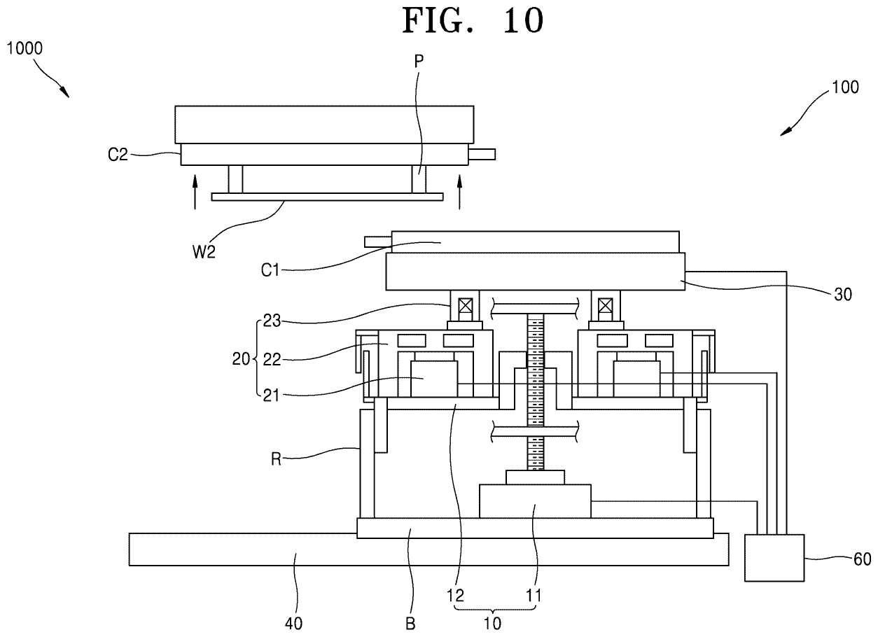

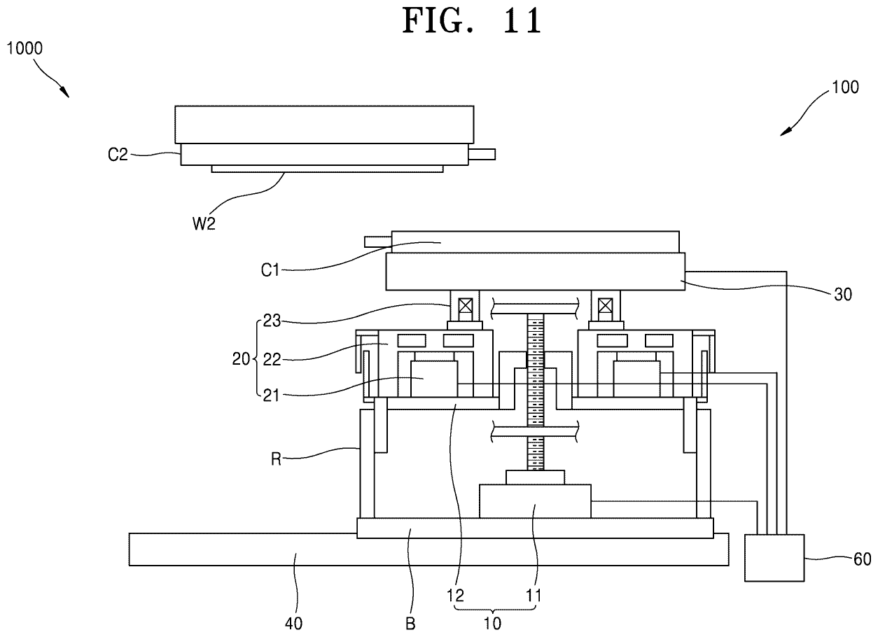

Next, as illustrated in FIG. 10, the picker P of the second wafer chuck C2 picks up the second wafer W2, and then, as illustrated in FIG. 11, the picker P ascends and brings the second wafer W2 into close contact with the second wafer chuck C2. The second wafer chuck C2 may then vacuum-adsorb and hold the adhered second wafer W2. Here, in addition to vacuum-adsorbing the back surface of the second wafer W2, various types of pickers that clamp the side of the second wafer W2 may also be applied.

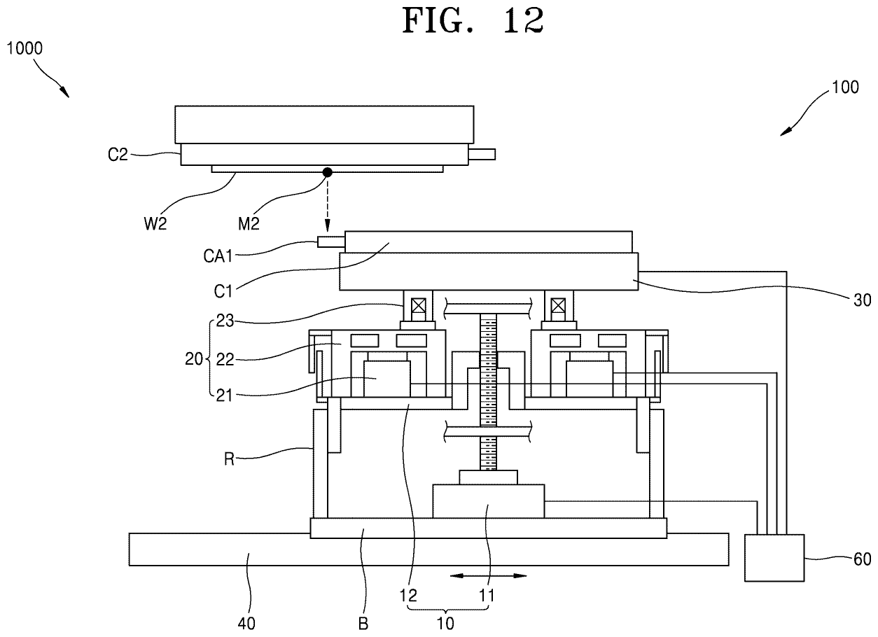

Subsequently, as shown in FIG. 12, the position of the second identifier M2 of the second wafer W2 vacuum-adsorbed to the second wafer chuck C2 may be identified using the first camera CA1 formed on either the first wafer chuck C1 or the alignment stage 30. In this instance, the second identifier M2 may include not only a separate identifier formed at the edge of the second wafer W2 but also various types of patterns formed on the front surface of the second wafer W2 that can serve as identifiers.

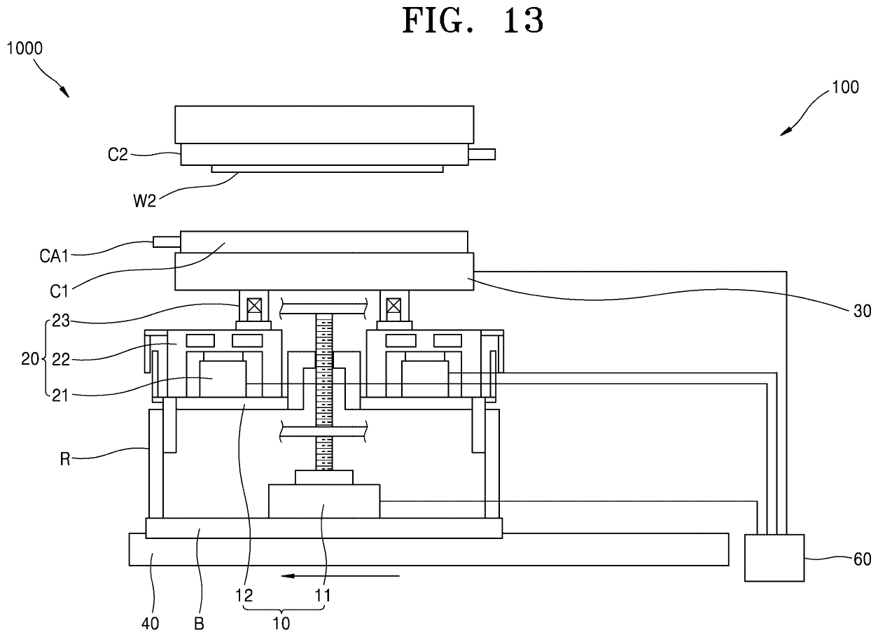

Then, as illustrated in FIG. 13, the base B may be transported along the second axis direction II (see FIG. 1) to a position corresponding to the second wafer chuck C2, to which the second wafer W2 has been held, using the transfer device 40.

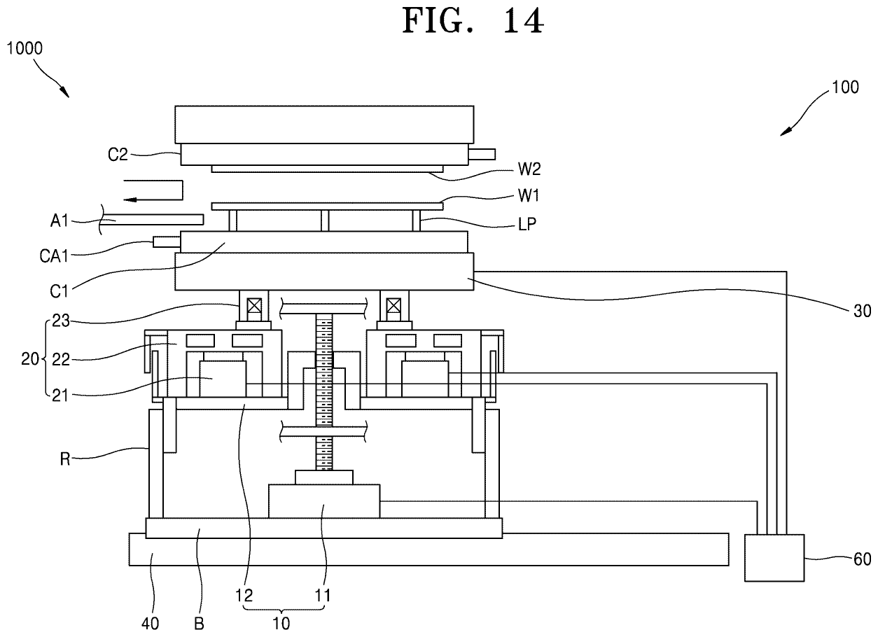

Subsequently, as illustrated in FIG. 14, the first wafer transfer arm A1 may load the first wafer W1 onto lift pins LP of the first wafer chuck C1. In this case, the first wafer transfer arm A1 may support the back surface of the first wafer W1, approach the space above the lift pins LP, and then descend to a height below upper ends of the lift pins LP to transfer the first wafer W1 to the lift pins LP.

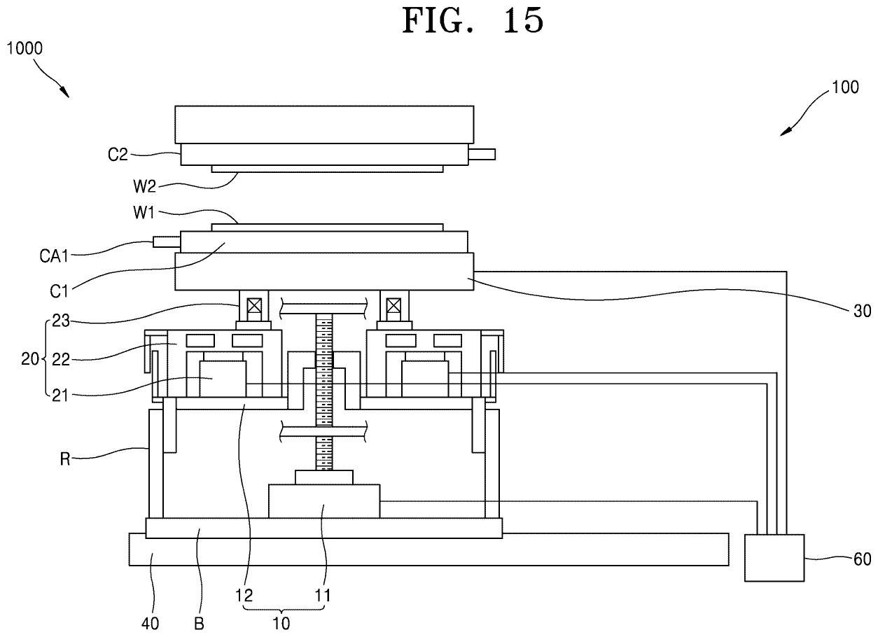

Next, as shown in FIG. 15, the lift pins LP may be lowered so that the first wafer chuck C1 vacuum-adsorbs and holds the first wafer W1. Then, as shown in FIG. 16, the first wafer chuck C1 may be elevated approximately by a first distance L1 with low precision using the first driving device 10.

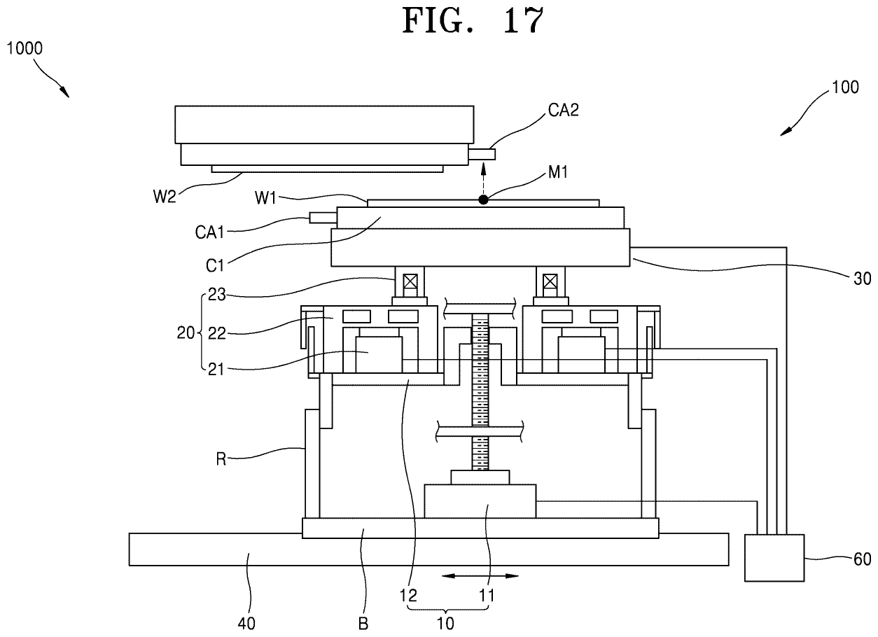

Thereafter, as illustrated in FIG. 17, the second camera CA2, which is formed on the second wafer chuck C2 and captures the first identifier M1 of the first wafer W1, and the alignment stage 30 may be used to precisely align the first wafer W1 with respect to the position-verified second wafer W2 in the first axis direction I (see FIG. 1), second axis direction II (see FIG. 1), and theta-axis direction R3 (see FIG. 1).

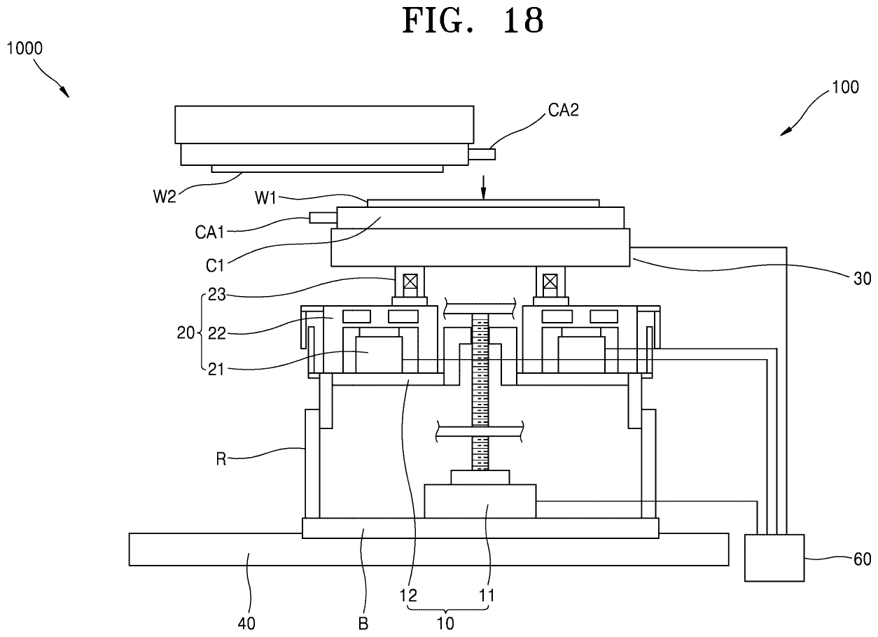

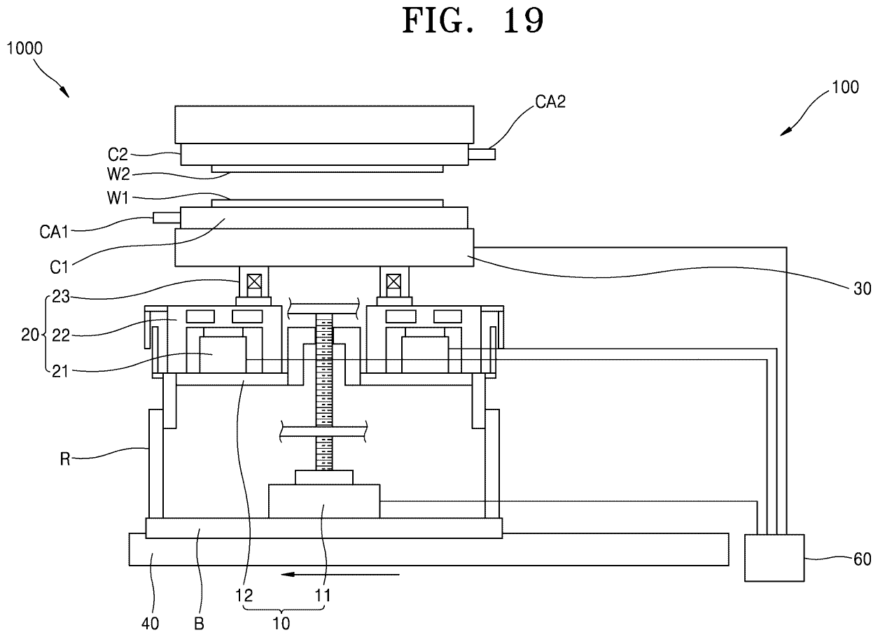

Subsequently, as illustrated in FIG. 18, the first wafer chuck C1 may be precisely lowered using the second driving device 20. Then, as illustrated in FIG. 19, the base B may be transported along the second axis direction II (see FIG. 1) to a position corresponding to the second wafer chuck C2, which holds the second wafer W2, using the transfer device 40.

As illustrated in FIG. 20, the first wafer chuck C1 may then be precisely raised by a second distance L2 with high precision using the second driving device 20 to bond the aligned first wafer W1 and second wafer W2. Here, the second distance L2 is a much shorter distance compared to the first distance L1 and may be exaggerated in the drawings for ease of explanation.

Accordingly, in the multi-axis stage apparatus 100 and the wafer bonding apparatus 1000 according to some embodiments of the present invention, the precision and speed of the wafer bonding process can be significantly improved by employing a dual-stage vertical movement configuration, that is a first driving device 10 with a long stroke and low precision, and a second driving device 20 with a short stroke and high precision, for vertical (Z-axis) motion. For example, whereas the repeatability precision in conventional systems may be on the order of ±100 nanometers, the present invention enables repeatability precision of approximately ±5 nanometers, significantly enhancing bonding accuracy.

Additionally, according to the present invention, mechanical errors or component damage during multi-axis actuation can be prevented by employing the first voice coil motor 21 and the flexure joint 23. Furthermore, mechanical and thermal deformation due to load can be prevented by distributing the load across multiple paths, thereby greatly improving productivity, durability, and reliability of the device.

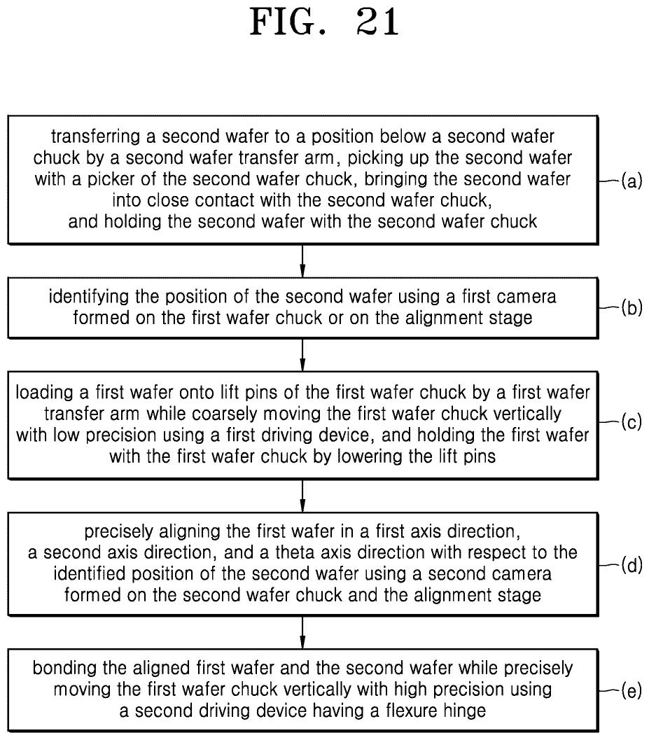

FIG. 21 is a flowchart illustrating a wafer bonding method using a multi-axis stage apparatus 100 according to some embodiments of the present invention.

As illustrated in FIGS. 1 to 21, a wafer bonding method using a multi-axis stage apparatus 100 according to some embodiments of the present invention may include the steps of (a) transferring the second wafer W2 below the second wafer chuck C2 using the second wafer transfer arm A2, wherein the picker P of the second wafer chuck C2 picks up the second wafer W2, brings it into close contact with the second wafer chuck C2, and the second wafer chuck C2 vacuum-adsorbs and holds the contacted second wafer W2, (b) identifying the position of a second identifier M2 of the second wafer W2 using a first camera CA1 formed on the first wafer chuck C1 or on the alignment stage 30, (c) coarsely moving the first wafer chuck C1 up and down with low precision using the first driving device 10, while the first wafer transfer arm A1 loads the first wafer W1 onto lift pins LP of the first wafer chuck C1, and then lowering the lift pins LP so that the first wafer chuck C1 vacuum-adsorbs and holds the first wafer W1, (d) precisely aligning the first wafer W1 with respect to the position-identified second wafer W2 in a first axis direction I, a second axis direction II, and a theta-axis direction R3 using the second camera CA2, which is formed on the second wafer chuck C2 to capture a first identifier M1 of the first wafer W1, and the alignment stage 30, and (e) bonding the aligned first wafer W1 and second wafer W2 by precisely moving the first wafer chuck C1 up and down with high precision using the second driving device 20 having the flexure hinge 224.

Although the present invention has been described with reference to the embodiments illustrated in the drawings, such embodiments are provided merely by way of example. It will be understood by those skilled in the art that various modifications and equivalent alternatives may be made without departing from the scope of the invention. Accordingly, the true technical scope of the present invention shall be defined by the spirit of the appended claims.

What is claimed is:

1. A multi-axis stage apparatus comprising:
a base;
an alignment stage for aligning a wafer chuck holding a first wafer;
a first driving device disposed between the base and the alignment stage and configured to move the alignment stage vertically with low precision; and
a second driving device disposed between the base and the alignment stage and configured to move the alignment stage vertically with high precision,
wherein the second driving device includes a flexure hinge having at least a portion configured to distribute a load.

2. The multi-axis stage apparatus of claim 1, wherein the second driving device comprises:
a plurality of first voice coil motors arranged isometrically around a central axis for vertical movement;
a movable stage having a flexure hinge, a portion of which is fixed and another portion of which is configured to move vertically with high precision by the first voice coil motors; and
a flexure joint formed in the movable stage and having multiple degrees of freedom.

3. The multi-axis stage apparatus of claim 2, wherein the movable stage comprises:
an inner pillar portion formed vertically and configured to distribute a load along a first path;
an outer pillar portion formed vertically and disposed outward of the inner pillar portion, the outer pillar portion being configured to distribute a load along a second path;
a precision elevation portion formed between the inner pillar portion and the outer pillar portion, configured to distribute a load along a third path and to move vertically with high precision by the first voice coil motors; and
flexure hinges respectively disposed between the inner pillar portion and the precision elevation portion and between the outer pillar portion and the precision elevation portion, the flexure hinges being configured to elastically support the precision elevation portion.

4. The multi-axis stage apparatus of claim 3, wherein the flexure hinge comprises:
an upper bridge portion formed above the precision elevation portion; and
a lower bridge portion formed in parallel with the upper bridge portion and spaced apart from the upper bridge portion by a gap so as to allow the precision elevation portion to move vertically, the lower bridge portion being formed at a middle or lower portion of the precision elevation portion.

5. The multi-axis stage apparatus of claim 2, wherein the first voice coil motors are quadrangularly or triangularly arranged around a nut member on the movable frame so as to allow the first wafer to rotate about a first rotational axis or a second rotational axis.

6. The multi-axis stage apparatus of claim 1, wherein the first driving device is configured to move at least a portion of the alignment stage in a third axis direction by a first distance with respect to the base;
the second driving device is configured to move at least a portion of the alignment stage in the third axis direction by a second distance with respect to the first driving device; and
the alignment stage is connected to the second driving device so that the first wafer can be movable in the third axis direction by a distance corresponding to the sum of the first distance and the second distance.

7. The multi-axis stage apparatus of claim 6, wherein the first driving device is configured to move the first wafer with low precision by a first distance that is relatively longer than the second distance; and the second driving device is configured to move the first wafer with high precision by a second distance that is relatively shorter than the first distance.

8. The multi-axis stage apparatus of claim 6, wherein the first driving device is configured to move the first wafer with low precision using a ball screw or a lead screw, by a displacement on the order of micrometers or millimeters; and
the second driving device is configured to move the first wafer with high precision using a voice coil motor or a piezoelectric element, by a displacement on the order of nanometers.

9. The multi-axis stage apparatus of claim 1, wherein the first driving device comprises:
a drive motor formed on the base and configured to rotate a screw shaft; and
a movable frame guided along a vertical movement path by a rail member formed on the base and including a nut member configured to move vertically by rotation of the screw shaft.

10. The multi-axis stage apparatus of claim 9, wherein the drive motor is a direct drive motor configured to directly rotate the screw shaft; and the movable frame includes a nut member threadably engaged with the screw shaft at a central portion thereof.

11. The multi-axis stage apparatus of claim 1, wherein the alignment stage is configured to align the first wafer in a first axis direction, a second axis direction, and a theta axis direction using a second voice coil motor or a piezoelectric element.

12. The multi-axis stage apparatus of claim 11, wherein the alignment stage comprises:
a stage jig;
a flexure frame having a portion fixed to the stage jig and another portion elastically deformable with respect to the stage jig; and
at least one second voice coil motor formed on the stage jig and configured to elastically deform the other portion of the flexure frame.

13. The multi-axis stage apparatus of claim 12, wherein the flexure frame comprises:
a fixed portion fixed to the stage jig;
a flexure hinge formed in the fixed portion and made of an elastic material; and
a movable portion configured to support the first wafer chuck and to be elastically displaced with high precision by the flexure hinge.

14. The multi-axis stage apparatus of claim 13, wherein the flexure hinge comprises:
a first hinge formed to extend in a first axis direction and configured to elastically deform in a second axis direction;
a second hinge formed to extend in a second axis direction and configured to elastically deform in a first axis direction; and
a rotational hinge formed in the movable portion and configured to allow the movable portion to rotate about a theta axis.

15. The multi-axis stage apparatus of claim 13, wherein the second voice coil motor comprises:
a first-axis forward voice coil motor formed on one side of the movable portion and disposed in a forward direction along a first axis direction;
a first-axis reverse voice coil motor formed on another side of the movable portion and disposed in a reverse direction along the first axis direction so as to allow the movable portion to move precisely in the first axis direction or rotate precisely about a theta axis;
a second-axis forward voice coil motor formed on a further side of the movable portion and disposed in a forward direction along a second axis direction; and
a second-axis reverse voice coil motor formed on yet another side of the movable portion and disposed in a reverse direction along the second axis direction so as to allow the movable portion to move precisely in the second axis direction or rotate precisely about the theta axis.

16. The multi-axis stage apparatus of claim 1, further comprising a transfer device configured to move the base forward and backward to a position corresponding to a second wafer chuck on which a second wafer is held, so as to enable bonding of the second wafer to the first wafer.

17. The multi-axis stage apparatus of claim 16, further comprising:
a first camera formed on the first wafer chuck or the alignment stage and configured to capture a second identifier of the second wafer;
a measurement device configured to measure a vertical movement distance of the first wafer or the first wafer chuck; and
a controller configured to receive an image signal from the first camera or a measurement signal from the measurement device, and to apply a control signal to at least one of the first driving device, the second driving device, the alignment stage, the transfer device, or any combination thereof.

18. The multi-axis stage apparatus of claim 17, wherein the controller is configured to:
apply a first-stage control signal to the first driving device in a first wafer loading mode in which the first wafer is loaded onto the first wafer chuck and the first wafer chuck holds the first wafer;
apply an alignment control signal to the alignment stage in an alignment mode in which the first wafer is precisely aligned in a first axis direction, a second axis direction, and a theta axis direction with respect to the second wafer whose position has been identified; and
apply a second-stage vertical control signal to the second driving device in a bonding mode in which the aligned first wafer and the second wafer are bonded.

19. A wafer bonding method using a multi-axis stage apparatus, comprising:
(a) transferring a second wafer to a position below a second wafer chuck by a second wafer transfer arm, picking up the second wafer with a picker of the second wafer chuck, bringing the second wafer into close contact with the second wafer chuck, and holding the second wafer with the second wafer chuck;
(b) identifying the position of the second wafer using a first camera formed on the first wafer chuck or on the alignment stage;
(c) loading a first wafer onto lift pins of the first wafer chuck by a first wafer transfer arm while coarsely moving the first wafer chuck vertically with low precision using a first driving device, and holding the first wafer with the first wafer chuck by lowering the lift pins;
(d) precisely aligning the first wafer in a first axis direction, a second axis direction, and a theta axis direction with respect to the identified position of the second wafer using a second camera formed on the second wafer chuck and the alignment stage; and
(e) bonding the aligned first wafer and the second wafer while precisely moving the first wafer chuck vertically with high precision using a second driving device having a flexure hinge.

20. A wafer bonding apparatus comprising:
a base;
an alignment stage configured to align a first wafer held by a first wafer chuck;
a first driving device formed between the base and the alignment stage and configured to move the alignment stage vertically with low precision; and
a second driving device formed between the base and the alignment stage and configured to move the alignment stage vertically with high precision,
wherein the second driving device includes:
a plurality of first voice coil motors isometrically arranged about a central axis for vertical movement;
a movable stage having a flexure hinge, a portion of which is relatively fixed and another portion of which is configured to move vertically with high precision by the first voice coil motors; and
a flexure joint formed on the movable stage and having multiple degrees of freedom, wherein the movable stage comprises:
an inner pillar portion formed vertically to distribute load along a first path;
an outer pillar portion formed vertically on an outer side of the inner pillar portion to distribute load along a second path;
a precision elevation portion formed between the inner and outer pillar portions to distribute load along a third path, the precision elevation portion being vertically movable with high precision by the first voice coil motors; and
wherein the flexure hinge is formed between the inner pillar portion and the precision elevation portion and between the outer pillar portion and the precision elevation portion to elastically support the precision elevation portion,
wherein the first driving device is configured to move at least a portion of the alignment stage in a third axis direction by a first distance relative to the base;
wherein the second driving device is configured to move at least a portion of the alignment stage in the third axis direction by a second distance relative to the first driving device;
wherein the alignment stage is connected to the second driving device such that the first wafer is movable in the third axis direction by a sum of the first distance and the second distance;
wherein the first driving device is configured to coarsely move the first wafer in the third axis direction by the first distance, which is relatively longer than the second distance, with low precision;
wherein the second driving device is configured to precisely move the first wafer in the third axis direction by the second distance, which is relatively shorter than the first distance, with high precision,
wherein the alignment stage is configured to align the first wafer in a first axis direction, a second axis direction, and a theta axis direction using a second voice coil motor or a piezoelectric element,
wherein the alignment stage comprises:
a stage jig;
a flexure frame having a portion fixed to the stage jig and another portion elastically deformable relative to the stage jig; and
at least one second voice coil motor formed on the stage jig and configured to elastically deform the other portion of the flexure frame.
